(19) United States
(12) Patent Application Publication
(10) Pub. No.: US 2022/0219969 A1
(43) Pub. Date: Jul. 14, 2022

(54) MEMS DEVICE WITH MEANDERING ELECTRODES

(71) Applicant: MURATA MANUFACTURING CO., LTD., Nagaokakyo-shi (JP)

(72) Inventor: Hannu VESTERINEN, Espoo (FI)

(21) Appl. No.: 17/570,895

(22) Filed: Jan. 7, 2022

(30) Foreign Application Priority Data
Jan. 13, 2021 (FI) 20215029

(51) Int. Cl. B81B 3/00

(52) U.S. Cl. CPC B81B 3/0086; B81B 2203/04; B81B 2201/0242; B81B 2201/0235

(57) ABSTRACT

This disclosure describes a microelectromechanical device comprising a mobile rotor and a fixed stator, a rotor electrode and a stator electrode. The rotor and stator electrodes are meandering electrodes which comprises two or more first lateral sections which lie on a first lateral baseline, a first lateral gap in the rotor electrode is adjacent to a second lateral gap in the stator electrode and at least partially aligned with said second lateral gap in the transversal direction.

### FIELD OF THE DISCLOSURE

The disclosure relates to microelectromechanical devices, and particularly to devices which comprise a mobile mass element which can move in relation to a surrounding fixed structure. The present disclosure further concerns electrodes which can be prepared on the mobile mass element and on the fixed structure to measure this movement.

### BACKGROUND OF THE DISCLOSURE

Microelectromechanical (MEMS) devices often comprise a mobile mass element, which may be called a rotor. The rotor is typically suspended from a fixed structure with flexible suspenders which allow the rotor to move in relation to the fixed structure. The fixed structure may be called a stator. The movement of the rotor may be measured with a capacitive transducer which comprises a set of elongated electrode structures on the rotor interdigitated with a corresponding set of elongated electrode structures on the stator.

FIGS. 1a and 1 b illustrate two ways of implementing a capacitive transducer with elongated electrodes. The figures illustrate a rotor 11 with a set of rotor electrodes 111-113 and a stator 12 with a set of stator electrodes 121-123. The arrow next to the rotor 111 illustrate its direction of movement (the x-direction). In FIG. 1a the rotor and stator electrodes extend in a direction (the y-direction) which is perpendicular to the direction in which the rotor 11 moves. The distance between each rotor/stator electrode increases or decreases in the x-direction as the rotor moves. In this measurement the capacitive response is sensitive to the displacement of the rotor, but the relationship between the response and the displacement is not linear.

In FIG. 1b the rotor and stator electrodes extend in the direction (the x-direction) in which the rotor 11 moves. FIG. 1c illustrates the position of a first rotor electrode 111 and a first stator electrode 121 when the rotor is in its rest position. FIG. 1d illustrates the positions of the same electrodes when the rotor has moved a distance Δx to the left from its rest position. The capacitance between the two electrodes increases when their overlap in the x-direction increases. In this measurement the relationship between the capacitive response and the displacement is linear, but the capacitance increase obtained in FIG. 1d is often quite small in relation to the capacitance measured in the rest position. The measurement signal is therefore not very sensitive.

### BRIEF DESCRIPTION OF THE DISCLOSURE

An object of the present disclosure is to provide an apparatus which alleviates the above disadvantages.

The object of the disclosure is achieved by an arrangement which is characterized by what is stated in the independent claim. The preferred embodiments of the disclosure are disclosed in the dependent claims.

The disclosure is based on the idea of utilizing rotor and stator and stator electrodes with a meandering shape. With a suitable arrangement such electrodes can be used to measure a capacitive response which is highly sensitive to rotor displacement and also exhibits a linear dependence on that displacement.

### BRIEF DESCRIPTION OF THE DRAWINGS

In the following the disclosure will be described in greater detail by means of preferred embodiments with reference to the accompanying drawings, in which

FIGS. 1a-1b illustrate capacitive transducers implemented with elongated electrodes.

FIGS. 1c-1d illustrate how the capacitance changes when the rotor moves.

FIGS. 2a-2c illustrate rotor and stator electrodes.

FIGS. 3a-3b illustrate the change in main capacitance in a measurement where the meanders of the rotor and stator electrodes are partially aligned in the initial position.

FIGS. 3c-3d illustrate the change in main capacitance in a measurement where the meanders of the rotor and stator electrodes are fully aligned in the initial position.

FIG. 3e illustrates stray capacitance components.

FIGS. 4a-4c illustrate design options for a meandering electrode.

FIGS. 5a-5b illustrate a device where a meandering rotor electrode is flanked by meandering stator electrodes on both sides.

### DETAILED DESCRIPTION OF THE DISCLOSURE

This disclosure describes a microelectromechanical device comprising a mobile rotor and a fixed stator which lie in a device plane defined by a lateral axis and a transversal axis. The transversal axis is orthogonal to the lateral axis, and the device comprises at least one measurement region where an edge of the rotor and an edge of the stator are separated from each other by a rotor-stator gap. A rotor electrode extends from the edge of the rotor toward the stator in the rotor-stator gap. A first stator electrode extends from the edge of the stator toward the rotor in the rotor-stator gap. The rotor electrode and the first stator electrode are adjacent and substantially parallel to each other in the rotor-stator gap.

The rotor electrode is a meandering electrode which comprises two or more first lateral sections which lie on a first lateral baseline, and each first lateral section is separated from the adjacent first lateral section on the first lateral baseline by a first lateral gap.

The first stator electrode is a meandering electrode which comprises two or more second lateral sections which lie on a second lateral baseline, and each second lateral section is separated from the adjacent second lateral section on the second lateral baseline by a second lateral gap. At least one first lateral gap is adjacent to at least one second lateral gap and at least partially aligned with said at least one second lateral gap in the transversal direction.

The rotor and stator electrodes are folded beams with a serpentine shape. In other words, each of these meandering electrodes is a beam with a set of consecutive turns. The folds in the beam may for example comprise a plurality of mutually perpendicular sections—lateral sections which are connected to each other by transversal sections. Lateral sections which lie on a first lateral baseline are in this case connected by transversal sections to lateral sections which lie on a different lateral baseline. The connecting structure which joins two lateral sections on the first baseline to each other thereby contains two transversal sections with an additional lateral section between them. The mutually perpendicular sections of the folded beam thereby form a narrow meandering electrode with a rectangular pattern

However, the folds in the beam and the resulting turns of the meandering electrode do not necessarily have to be perpendicular. Instead of being connected to each other with a square- or rectangle-shaped folding, the lateral sections which lie on the same axis can alternatively be connected with a connecting structure with some other geometry, as described and illustrated in more detail below.

Although general measurement and design principles will be discussed below with reference to figures which illustrate just one or two elongated electrodes in each set of rotor and stator electrodes, the sets could be expanded to include any number of electrodes. Any principle which applies to an illustrated rotor—stator electrode pair will apply also to additional rotor—stator electrode pairs which are arranged adjacent to each other with the same geometry.

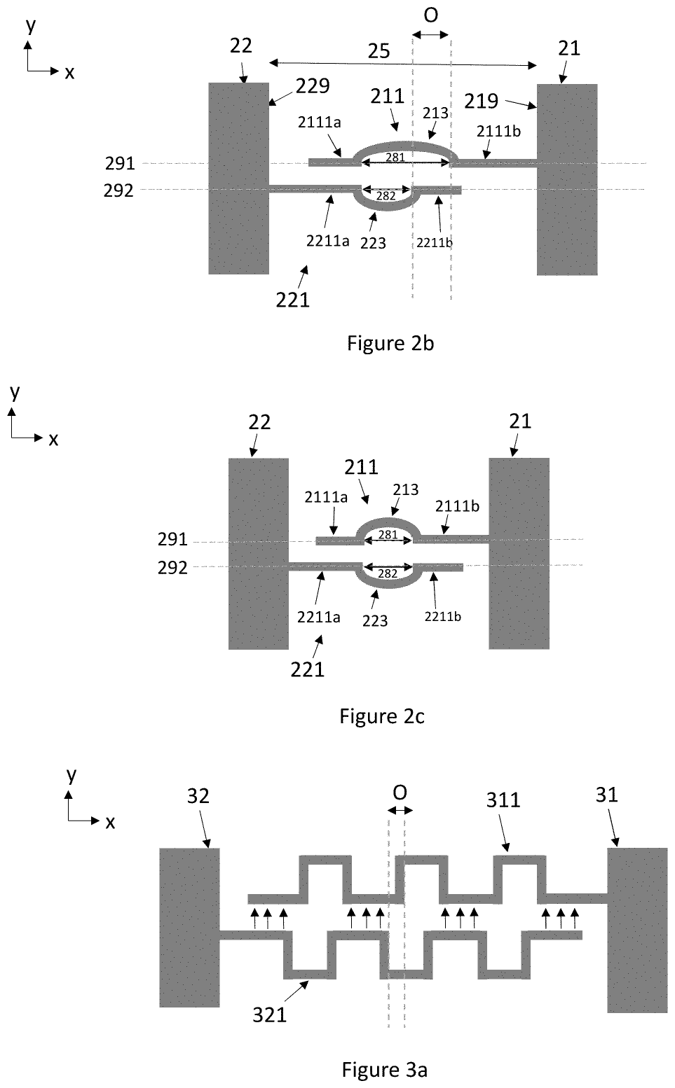

FIG. 2a illustrates a rotor 21 and a stator 22. A rotor electrode 211 extends from the edge 219 of the rotor 21 toward the stator 22, and a first stator electrode 221 extends from the edge 229 of the stator 22 toward the rotor 21. The rotor and stator electrodes have a meandering shape. The lateral direction is the x-direction and the transversal direction is the y-direction. The edge 219 of the rotor is separated from the edge 229 of the stator by a rotor-stator gap 25.

The rotor electrode 211 comprises first lateral sections 2111a and 2111b which lie on a first lateral baseline 291. Two first lateral sections are illustrated, but many more could be used. Each pair of first lateral sections (2111a+2111b) is separated from each other on the first lateral baseline 291 by a first lateral gap 281. Each first lateral section 2111a is connected to the following first lateral section 2111b by a first connecting structure 213 which extends away from the first lateral baseline 291, leaving the first lateral gap 281 between the first lateral sections 2111a and 2111b. These first connecting structures 213 could be of any shape and size which is suitable for separating the first lateral sections from each other by the desired first lateral gaps 281.

The first stator electrode 221 comprises second lateral sections 2211a and 2211b which lie on a second lateral baseline 292. Each pair of second lateral sections (2211a+2211b) is separated from each other on the second lateral baseline 292 by a second lateral gap 282. Each second lateral section 2211a is connected to the following second lateral section 2211b by a second connecting structure 223 which extends away from the second lateral baseline 292. The shapes of these second connecting structures 223 can also be freely selected, as long as they separate the second lateral sections from each other by the desired second lateral gaps 282.

FIG. 2a illustrates a situation where the rotor 211 is in an initial position. In any embodiment of this disclosure, the initial position may for example be a rest position which the rotor assumes in an accelerometer when the accelerometer does not experience any acceleration in the direction of the x-axis. Alternatively, if the rotor and stator are used in a gyroscope, the rotor may for example be driven in linear primary oscillation in the direction of the y-axis. It may oscillate in the direction of the x-axis when the gyroscope undergoes rotation about a z-axis perpendicular to the xy-plane. In this case the initial position may be defined by the x-coordinate of the rotor when the gyroscope does not undergo any rotation about the z-axis. In either case, a capacitive measurement can be performed between the rotor and stator electrodes. The measured capacitance indicates the displacement of the rotor away from its initial position in the direction of the x-axis, i.e. the lateral direction. The words “left” and “right” refer in this disclosure to two opposing lateral directions which correspond to the left and right sides of the figures.

FIG. 2a illustrates an arrangement where the at least one first lateral gap 281 is partially aligned with the at least one second lateral gap 282 in the transversal direction when the rotor 21 is in its initial position. This means that there is a lateral offset between at least one side of the gaps (left or right side, or on both sides). FIG. 2a shows an arrangement where the widths of the gaps 281 and 282 are equal, and each side of the second lateral gap 282 is offset from the corresponding side of the first lateral gap 281 by the same lateral offset distance O.

In any embodiment of this disclosure where lateral gaps are partially aligned, each pair of partially aligned lateral gaps may be arranged so that the lateral distance from the left side of the first lateral gap 281 to the left side of the second lateral gap 282 (a distance which corresponds to the offset distance O in FIG. 2a) is less than the lateral distance from the left side of the first lateral gap 281 to the right side of the second lateral gap 282 (a distance which is indicated as D in FIG. 2a). Alternatively or complementarily, the lateral distance (not illustrated in FIG. 2a) from the right side of the second lateral gap 282 to the right side of the first lateral gap 281 may be less than the lateral distance from the right side of the second lateral gap 282 to the left side of the first lateral gap 281 (indicated as D in FIG. 2a). However, the relationship between these distances could alternatively be the opposite (D could be less than O in FIG. 2a).

The first and second lateral gaps 281 and 282 do not necessarily need to have the same width when the gaps are partially aligned. FIG. 2b illustrates an alternative arrangement where the widths differ from each other and where only the right side of the second lateral gap 282 is laterally offset from the right side of the first lateral gap 281. The left sides of the two gaps are aligned with each other.

The at least one first lateral gap 281 may alternatively be fully aligned with the at least one second lateral gap 282 in the transversal direction when the rotor 21 is in its initial position. This option is illustrated in FIG. 2c. In this case the first and second lateral gaps have the same lateral width and there is no lateral offset between the two gaps. Both the left and the rights sides of the gaps are aligned with each other.

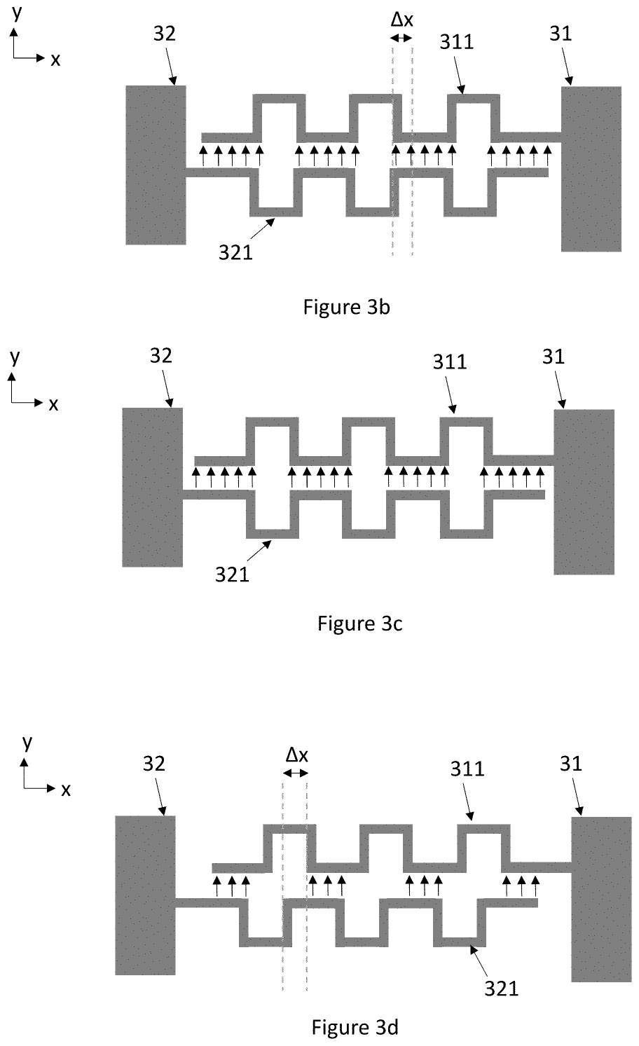

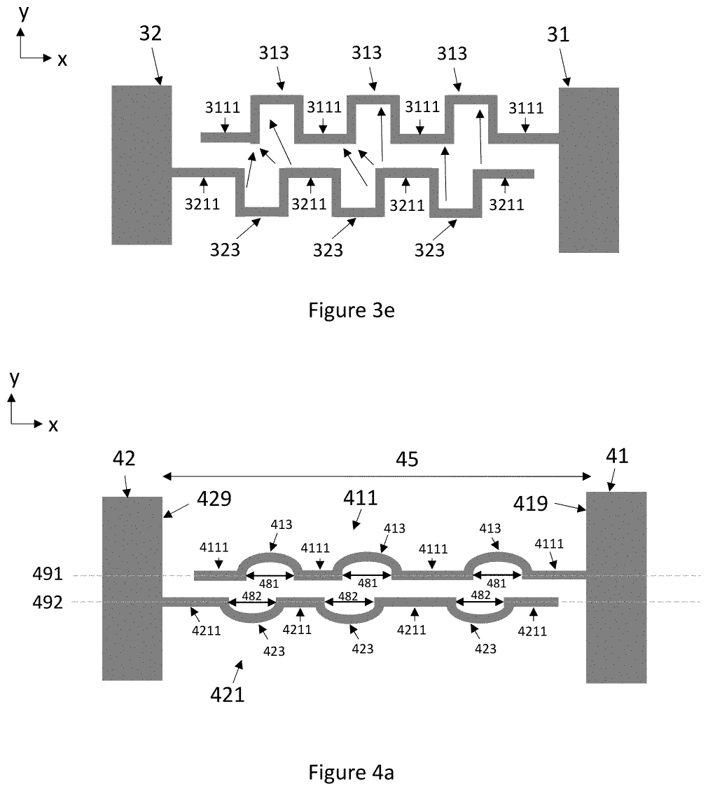

The principles of the capacitive measurement will be described with reference to FIGS. 3a-3c, where reference numbers 31, 32, 311 and 321 correspond to reference numbers 21, 22, 211 and 221, respectively, in FIGS. 2a-2c.

FIG. 3a illustrates the rotor and stator electrodes 311 and 321 when the rotor is in the initial position. The meanders in the rotor electrode are offset from the corresponding meanders on the stator electrode by a lateral offset distance O. The main components of the capacitance between the rotor and stator electrodes in FIG. 3a arise from the areas which are closest to each other. These components are illustrated by arrows, and their sum will be referred to as the main capacitance. Additional, but smaller, capacitive components arise in the areas which are not directly adjacent to each other. The sum of these components may be referred to as the stray capacitance.

FIG. 3b illustrates a situation where the rotor 31 has been displaced to the left from the initial position by a distance Δx. Due to the fact that the meanders of the rotor electrode 311 and those of the stator electrode 312 were offset from each other by an offset distance O in the initial position illustrated in FIG. 3a, the main capacitance is larger in FIG. 3b than in FIG. 3a. The movement of the rotor 31 in the x-direction has brought the meanders almost into alignment with each other in the direction of the y-axis. The overlap between the lateral sections which lie closest to each other has therefore increased.

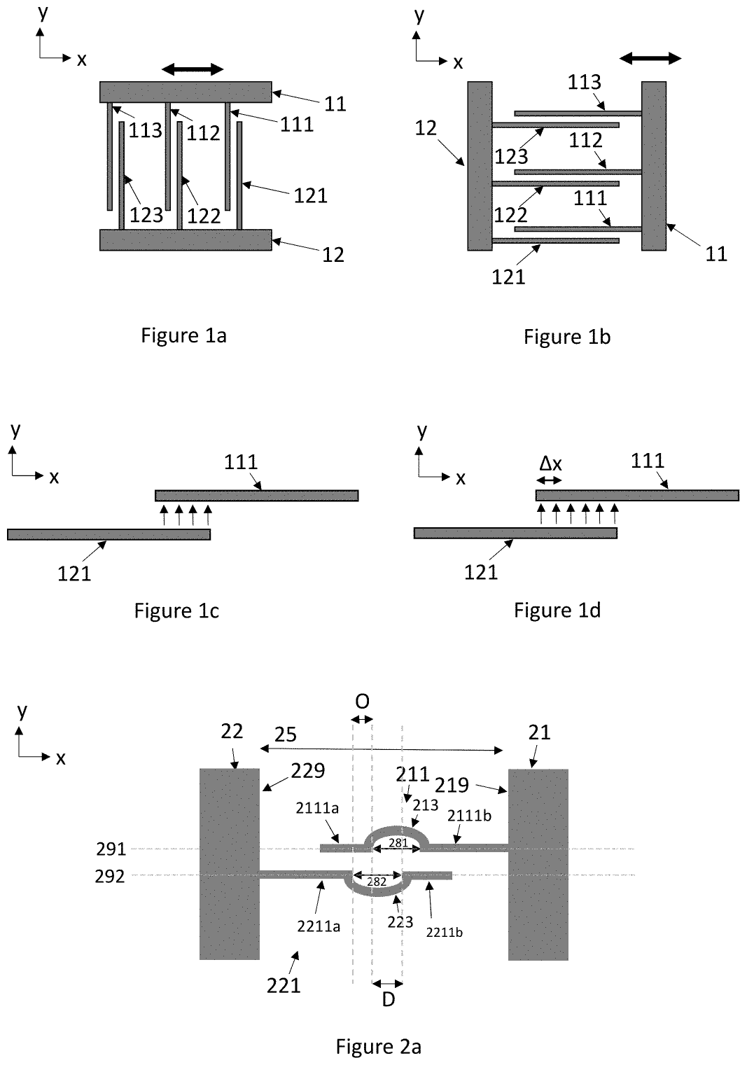

It is significant that every lateral section in the meander contributes an additional increase to the main capacitance. This can schematically be compared to the movement illustrated in FIG. 1d, where the capacitance increase was illustrated with only two additional arrows compared to FIG. 1c. In contrast, in FIG. 3b each lateral section in the meandering electrode contributes to the increase in main capacitance with two additional arrows compared to FIG. 3a. The original 12 arrows of the initial position in FIG. 3a thereby become 20 arrows in FIG. 3b. Electrodes with a meandering shape can therefore produce a capacitive response which is both linear and highly sensitive because the capacitive area will increase at each turn in the meander in FIG. 3b, not merely at the tip of the electrode as in FIG. 1d.

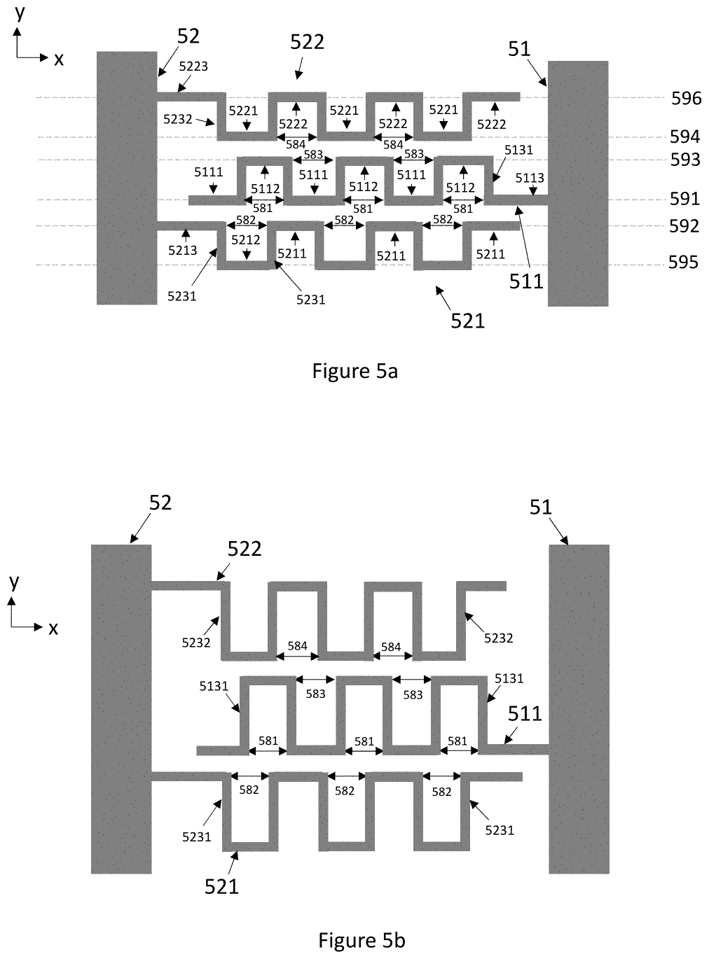

The sensitivity can be increased by increasing the number of lateral sections in each electrode—i.e. by increasing the number of turns in the meander. However, some practical constraints have to be observed. In the arrangement illustrated in FIGS. 3a-3b, the meandering shapes and their offset have been designed so that the expected maximum displacement Δxₘₐₓ (which is here assumed to be approximately equal to the Δx illustrated in FIG. 3b) is not greater than the offset distance O in FIG. 3a. If this would not be the case, and if the rotor 31 would move to the left a distance which exceeds the offset distance, then the overlap between the adjacent meander turns (and thereby the main capacitance) would begin to decrease as a function of displacement when the rotor electrode 311 moves further past the stator electrode 321 than where it is illustrated in FIG. 3b. The measured capacitance values would then not exhibit a linear dependence on displacement, and some capacitance values would correspond to multiple displacement values. The offset should therefore exceed the expected maximum displacement in the embodiments illustrated in FIGS. 2a and 2b, and in FIGS. 5a and 5b below.

FIGS. 3c-3d illustrate the measurement which can be performed when the first and second lateral gaps are fully aligned in the initial position, as in FIG. 2c. FIG. 3c illustrates the initial position where the meander curves of the rotor and stator electrode are fully aligned with each other in the transversal direction (the y-direction). The main capacitance is at a maximum in the illustrated initial position (illustrated by 20 arrows). FIG. 3d illustrates a situation where the rotor has moved away from the initial position to the right. The main capacitance has decreased so that only 12 arrows are left. A corresponding decrease in capacitance would be obtained if the rotor moved to the left. The movement of the rotor 31 may in this embodiment be restricted either to rightward movement or to leftward movement from the initial position, because these two movements cannot be distinguished from each other in the capacitive measurement.

In FIG. 3d the expected maximum displacement Δxₘₐₓ should be less than the widths of the first and second lateral sections and the widths of the first and second lateral gaps. If this would not be the case, the overlap between the adjacent meanders (and thereby the main capacitance) would not decrease as a linear function of displacement.

FIG. 3e illustrates the rotor in the same initial position as in FIG. 3a. Reference numbers 313 and 323 correspond to reference numbers 213 and 223, respectively, in FIG. 2a. Reference number 3111 corresponds to reference numbers 2111a and 2111b, and reference number 3211 corresponds to 2211a and 2211b in FIGS. 2a-2c. The arrows between the rotor electrode and the first stator electrode here illustrate the components which contribute to stray capacitance. These may include the capacitance between any first or second lateral section 3111/3211 and the opposing connecting section 313/323, the capacitance between first and second lateral sections which are not adjacent to each other, and the capacitance between opposing connecting sections 313/323. The magnitude of the stray capacitance will depend on the distance between the rotor and stator electrodes and on their geometry and dimensions.

The measured capacitance will always be a sum of the main capacitance and the stray capacitance, and the stray capacitance will not in general exhibit a completely linear dependence on displacement. However, the main capacitance can be much larger than the stray capacitance since the regions where the electrodes are closest to each other will contribute most to the capacitance between. The influence of the stray capacitance on the measured capacitance can also be minimized with suitable electrode design.

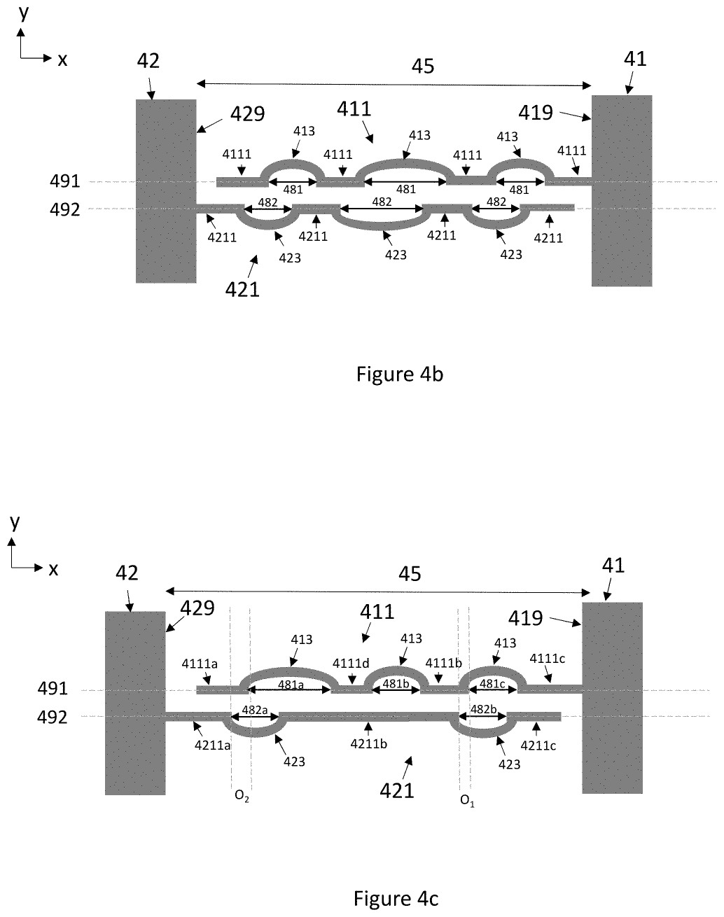

FIGS. 4a-4c illustrate some options for electrode design. Reference numbers 41, 42, 411, 419, 421, 413, 423, 429, 481, 482, 491 and 492 correspond to reference numbers 21, 22, 211, 219, 221, 213, 223, 229, 281, 282, 291 and 292, respectively, in FIGS. 2a-2c. Reference number 4111 corresponds to reference numbers 2111a and 2111b, and reference number 4211 corresponds to 2211a and 2211b in FIGS. 2a-2c.

FIG. 4a illustrates a rotor electrode with four first lateral sections 4111, four second lateral sections 4211, three first lateral gaps 481 and three second lateral gaps 482. The figure illustrates the rotor in its initial position. Each first lateral gap 481 is in FIG. 4a laterally offset from the adjacent second lateral gap 482 by the same lateral offset distance. However, the lateral offset distance does not necessarily have to be equal for each pair of first and second lateral gaps as long as the expected maximum displacement of the rotor is less than the smallest lateral offset in the direction of motion.

Each first lateral gap and each second lateral gap may have the same lateral width, as FIG. 4a illustrates. Alternatively, the widths of some first or second lateral gaps may be different, as FIG. 4b illustrates. Each first lateral section and each second lateral section may have the same lateral width, as FIG. 4b illustrates. Alternatively, some first lateral sections may have widths which differ both from the widths of other first lateral sections and from the widths of some second lateral sections, as FIG. 4a illustrates.

The rotor electrode may have a separate base section which is attached to the edge 419 of the rotor, and the first lateral sections 4111 and first connecting structures 413 may be connected in an alternating series to this base section. The first stator electrode could have a corresponding base section to which the second lateral sections 4211 and second connecting structures 423 are connected in an alternating series. The shapes and sizes of these base sections could differ from the shapes and sizes of the first and second lateral sections. Base sections have not been illustrated in FIG. 4a.

The number of first and second lateral gaps does not necessarily have to be equal, and each first lateral gap 481 does not necessarily have to be aligned with a corresponding second lateral gap 482. This is illustrated in FIG. 4c, where no second lateral gap on the first stator electrode is adjacent to first lateral gap 481b on the rotor electrode. The number of first lateral sections 4111a-4111d is four, but the number of second lateral sections 4111a-4111c is three. The capacitance between the rotor electrode 411 and the first stator electrode 421 will nevertheless increase when the rotor moves to the left and the overlap between the pairs 4111a+4211a, 4111b+4211b and 4111c+4211c increases. The extra first lateral section 4111d and the extra first lateral gap 481b will remain fully aligned with the long second lateral section 4211 as the rotor moves to the left, so they will not contribute to a change in capacitance. FIG. 4c also illustrates a device where the lateral offsets O₁ and O₂ of two second lateral gaps 482a and 482b from the corresponding first lateral gaps 481a and 481c are not equal in the initial position.

FIG. 5a illustrates a device where the rotor electrode further comprises two or more third lateral sections 5112 which lie on a third lateral baseline 593. Each third lateral section 5112 is separated from the adjacent third lateral section 5112 on the third lateral baseline 593 by a third lateral gap 583.

A second stator electrode 522 extends from the edge of the stator 52 toward the rotor 51 in the rotor-stator gap. The rotor electrode 511 and the second stator electrode 522 are adjacent and substantially parallel to each other in the rotor-stator gap.

The second stator electrode 522 is a meandering electrode which comprises two or more fourth lateral sections 5221 which lie on a fourth lateral baseline 594. Each fourth lateral section 5221 is separated from the adjacent fourth lateral section 5221 on the fourth lateral baseline 594 by a fourth lateral gap 584. The second stator electrode is a folded beam with a serpentine shape.

The first lateral baseline 591 lies between the second lateral baseline 592 and the third lateral baseline 593. The third lateral baseline 593 lies between the first lateral baseline 591 and the fourth lateral baseline 594.

Each third lateral gap 583 is adjacent to one of the fourth lateral gaps 584. Each third lateral gap 583 is at least partially aligned with said fourth lateral gap 584 in the transversal direction. The lateral widths of all third and fourth lateral gaps 583/584 are equal to the lateral widths of the first and second lateral gaps 581/582. The widths of all of the two or more first, second, third and fourth second lateral sections 5111/5211/5112/5221 are also equal.

Each connecting structure on the rotor electrode in FIG. 5a comprises two transversal sections such as 5131, attached to the ends of the adjacent first lateral sections 5111. Each connecting structure on the rotor electrode also comprises a third lateral section 5112 which extends between the two transversal sections 5131. The connecting structures on the first stator electrode 521 could be the same as in FIG. 2a, and similar connecting structures could be employed in the second stator electrode 522. However, FIG. 5a illustrates electrodes where the connecting structures on the first and second stator electrodes comprise two transversal sections (such as 5231 and 5232) joined together by additional lateral sections (such as 5212 and 5222).

The lateral widths of these additional lateral sections may be equal to the lateral widths of the first, second, third and fourth lateral sections. Furthermore, the transversal lengths of the transversal sections 5131, 5231 and 5232 may be equal to the lateral widths of all lateral sections. This yield the square-shaped meander shown in FIG. 5a, where the gaps between all lateral sections have the same width.

As in FIG. 2a, each first lateral gap 581 in FIG. 5a is at least partially aligned with a second lateral gap 582 in the initial position. Furthermore, each third lateral gap 583 is at least partly aligned with a fourth lateral gap 584 in the initial position. Each of these alignments could be complete, as in FIG. 2c or 3c, or partial as in FIG. 2a-or 2c.

As before, in partial alignment each first lateral gap 581 in FIG. 5a is laterally offset from the corresponding second lateral gap 582 by the same lateral offset distance O. Furthermore, each third lateral gap 583 may be laterally offset from the corresponding fourth lateral gap 584 by the same lateral offset distance O. In full alignment, each third lateral gap 583 is fully aligned with each fourth lateral gap 584 in the initial position, and each first lateral gap 581 is fully aligned with each second lateral gap 582.

The part of the rotor/stator electrodes which is closest to the edge of the rotor/stator may be called a base section, as mentioned above. FIG. 5a illustrates base sections 5113, 5213 and 5223 which are longer than the first (5111), second (5211), third (5111) and fourth (5221) lateral sections.

FIG. 5b illustrates an alternative configuration where lateral widths of the first (5111), second (5211), third (5111) and fourth (5221) lateral sections are all equal, but the transversal lengths of the transversal sections 5131, 5231 and 5232 are greater than the lateral widths of the lateral sections. This yields the rectangle-shaped meander illustrated in the figure. The embodiments illustrated in FIGS. 5a and 5b could also be combined, for example so that the transversal sections on the rotor electrode are longer than the transversal sections on the stator electrode, or vice versa.

When the meander pattern of the first stator electrode 521 is aligned with the meander pattern of the second stator electrode 522 in the transversal direction as FIGS. 5a and 5b illustrates, both sides 5111/5112 of the meandering rotor electrode will contribute to the main capacitance between the rotor and stator electrodes. Furthermore, with the square- or rectangular-shaped meanders illustrated in these figures, a portion of the stray capacitance (the portion which corresponds to the capacitance arrows which are parallel to the y-axis in FIG. 3e) will exhibit a linear dependence on displacement. The number of rotor and stator electrodes could be increased further, and the meander pattern of all additional rotor and stator electrodes may be fully aligned with the illustrated rotor and stator electrodes in the transversal direction. Small offsets in the additional rotor/stator electrode meanders (in relation to the illustrated meanders) are also possible. In any embodiment of this disclosure, the microelectromechanical device may comprise a set of meandering rotor electrodes which extend from the edge of the rotor toward the stator in the rotor-stator gap, and a corresponding set of meandering stator electrodes which extend from the edge of the stator toward the rotor in the rotor-stator gap.

The set of meandering rotor electrodes may be interdigitated with the set of meandering stator electrodes. The transversal distance from each rotor electrode to the two adjacent stator electrodes may be equal. In other words, the transversal distance between baselines 591 and 592 may be equal to the transversal distance between baselines 593 and 594 in FIG. 5a, and baselines 595 and 596 may be separated by the same transversal distance from the baselines of the next rotor electrodes (which are not illustrated in the figure).

Alternatively, the rotor and stator electrodes may be organized pairwise so that a first transversal distance from each rotor electrode to the stator electrode on one side (for example to the electrode below, i.e. the distance between 591 and 592 in FIG. 5a) is L₁, and a second transversal distance from the same rotor electrode to the stator electrode on the other side (above, i.e. the distance between 593 and 594) is L₂. The distance L₁ may differ from L₂, but each rotor electrode may be separated from the adjacent stator electrodes by the same first and second transversal distances L₁ and L₂.

In all embodiments presented in this disclosure, meandering rotor and stator electrodes comprise lateral sections separated by lateral gaps. In some embodiments, the lateral sections of the rotor electrode are partially aligned with the lateral sections of the stator electrode in the initial position, and their degree of alignment increases when the rotor is displaced. The capacitance between the rotor and stator electrode then also increases as a function of displacement. In other embodiments, the lateral sections of the rotor electrode are fully aligned with the lateral sections of the stator electrode in the initial position, and their degree of alignment decreases when the rotor is displaced. The capacitance between the rotor and stator electrode then also decreases as a function of displacement.

1. A microelectromechanical device comprising a mobile rotor and a fixed stator which lie in a device plane defined by a lateral axis and a transversal axis, whereby the transversal axis is orthogonal to the lateral axis, and the device comprises at least one measurement region where an edge of the rotor and an edge of the stator are separated from each other by a rotor-stator gap, and a rotor electrode extends from the edge of the rotor toward the stator in the rotor-stator gap, and a first stator electrode extends from the edge of the stator toward the rotor in the rotor-stator gap, and the rotor electrode and the first stator electrode are adjacent and substantially parallel to each other in the rotor-stator gap,
wherein the rotor electrode is a meandering electrode which comprises two or more first lateral sections which lie on a first lateral baseline, and each first lateral section is separated from the adjacent first lateral section on the first lateral baseline by a first lateral gap, wherein the rotor electrode is a folded beam with a serpentine shape,
and the first stator electrode is a meandering electrode which comprises two or more second lateral sections which lie on a second lateral baseline, and each second lateral section is separated from the adjacent second lateral section on the second lateral baseline by a second lateral gap, wherein the stator electrode is a folded beam with a serpentine shape,
wherein at least one first lateral gap is adjacent to at least one second lateral gap and at least partially aligned with said at least one second lateral gap in the transversal direction.

2. The microelectromechanical device according to claim 1, wherein said at least one first lateral gap is partially aligned with said at least one second lateral gap in the transversal direction when the rotor is in its initial position.

3. The microelectromechanical device according to claim 1, wherein said at least one first lateral gap is fully aligned with said at least one second lateral gap in the transversal direction when the rotor is in its initial position.

4. The microelectromechanical device according to claim 1, wherein each first lateral gap and each second lateral gap has the same lateral width.

5. The microelectromechanical device according to claim 1, wherein each first lateral section and each second lateral section has the same lateral width.

6. The microelectromechanical device according to claim 5, wherein the rotor electrode further comprises two or more third lateral sections which lie on a third lateral baseline, and each third lateral section is separated from the adjacent third lateral section on the third lateral baseline by a third lateral gap,
and a second stator electrode extends from the edge of the stator toward the rotor in the rotor-stator gap, so that the rotor electrode and the second stator electrode are adjacent and substantially parallel to each other in the rotor-stator gap,
and the second stator electrode is a meandering electrode which comprises two or more fourth lateral sections which lie on a fourth lateral baseline, and each fourth lateral section is separated from the adjacent fourth lateral section on the fourth lateral baseline by a fourth lateral gap, wherein the second stator electrode is a folded beam with a serpentine shape,
and the first lateral baseline lies between the second lateral baseline and the third lateral baseline, and the third lateral baseline lies between the first lateral baseline and the fourth lateral baseline,
wherein each third lateral gap is adjacent to one of the fourth lateral gaps and each third lateral gap is at least partially aligned with said fourth lateral gap in the transversal direction, and the lateral widths of all third and fourth lateral gaps are equal to the lateral widths of the first and second lateral gaps, and the lateral widths of all of the two or more first, second, third and fourth second lateral sections are equal.
